(19) United States
(12) Patent Application Publication
(10) Pub. No.: US 2007/0126057 A1
(43) Pub. Date: Jun. 7, 2007

(54) Lateral DMOS device insensitive to oxide corner loss

(76) Inventors: Jing-Meng Liu, Hsinchu (TW); Hung-Der Su, Luju Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/605,438

(22) Filed: Nov. 29, 2006

(30) Foreign Application Priority Data
Dec. 7, 2005 (TW) 094143206

(51) Int. Cl. H01L 29/76

(52) U.S. Cl. 257/335

(57) ABSTRACT

In a lateral DMOS device which has a drain diffusion region, an insulator is provided on the drain diffusion region. The insulator is helpful to reduce the lateral electric field under silicon surface. The gate of the DMOS does not overlap with the insulator over the drain diffusion region such that the lateral DMOS device is insensitive to oxide corner loss.

### FIELD OF THE INVENTION

The present invention is related generally to a metal-oxide- semiconductor (MOS) device and, more particularly, to a lateral double- diffused metal-oxide-semiconductor (DMOS) device having improved breakdown voltage and on-resistance characteristics.

### BACKGROUND OF THE INVENTION

DMOS devices are widely used as power switches in high voltage applications, and breakdown voltage and on-resistance optimization are two key factors for DMOS performance evaluation. In order to minimize power dissipation from such devices, it is desirable that they operate at a relatively low on-resistance. Likewise, it is desirable to have a relatively high breakdown voltage in order to protect the devices and the circuits connected to them. However, high breakdown voltage requirements are contrary to those for achieving low on-resistance.

In conventional lateral DMOS devices such as that shown in FIG. 1, a gate 12 is formed above a silicon substrate 10 with a gate oxide 14 therebetween, and a pair of N+ source 16 and drain 18 are formed on the substrate 10 at the opposite sides of the gate 12 and are self-aligned with the edges of the gate 12. Moreover, a P region 20 which is known as P-body is formed on the substrate 10 to have the source 16 therewithin and provide a portion thereof as part of the channel under the gate 12. Between the P region 20 and the drain 18, the substrate 10 have a region under the gate 12 which is known as drain diffusion region. The highest electric field that initiates avalanche breakdown generally occurs at the interface between the gate 12 and the drain 18, and it is therefore desirable to lower the maximum electric field at this location and at the same time spread the electric field profile more uniformly in order to sustain the breakdown voltage. Lower doped substrate 10 will result in higher breakdown voltage, but imparts greater on-resistance simultaneously. In addition, because the gate 12 extends over the entire drain diffusion region, carrier potential under the edge of the gate 12 that is close to the drain 18 will be much higher, and when carriers are attracted by gate bias to inject to the gate 12, hot carrier effect is easily induced and thereby reduces the lifetime of the device. The gate 12 extending over the entire drain diffusion region also results in the vertical electric field across the gate oxide 14 too high and easily causes the gate oxide 14 to breakdown. In addition, the lateral electric field at the silicon surface is also too high.

It is well known in the art to increase breakdown voltage by increasing the distance between the drain and the gate. As shown in FIG. 2, longer drain diffusion region improves the breakdown voltage of the DMOS device. Moreover, since the gate 12 is farther away from the drain 18, carrier potential under the edge of the gate 12 is lower, and therefore hot carrier effect is reduced. The vertical electric field across the gate oxide 14 is also reduced, and the gate oxide 14 would no longer easily breakdown accordingly. However, the longer drain diffusion region also undesirably increases the on-resistance and results in greater device size of the lateral DMOS device. Moreover, the lateral electric field at the silicon surface is still too high.

A drain extension region 22 is provided between the drain 18 and the gate 12 as shown in FIG. 3, which has the same conductivity type as the drain 18 and a dopant concentration between that in the drain 18 and the substrate 10, in order to reduce the on-resistance for the device. However, the lateral electric field at the silicon surface is still too high.

A reduced surface field (RESURF) DMOS such as that shown in FIG. 4 is proposed which significantly reduces the lateral electric field by providing a field oxide 24 on the drain diffusion region. However, when the gate oxide 14 is formed, the silicon surface sinks because of the superficial silicon consumed during the oxidization procedure. Moreover, several processes before the gate oxide 14 is formed may etch part of the field oxide 24 and thereby a recessed oxide corner will be formed at the edge of the field oxide 24. Due to the silicon lattice orientation of the recessed oxide corner different from that at the silicon surface, the oxide layer formed at this location thereafter is usually thinner, and therefore the breakdown and reliability of the DMOS device are sensitive to oxide corner loss.

More complicated structures have been proposed, for example by U.S. Pat. No. 6,946,705 to Kitaguchi, but require too complicated manufacture processes.

### SUMMARY OF THE INVENTION

An object of the present invention is to provide a lateral DMOS device which is insensitive to oxide corner loss.

Another object of the present invention is to provide a DMOS device whose lateral electric field is reduced.

Still another object of the present invention is to provide a DMOS device whose vertical electric field across gate dielectric is reduced.

Yet another object of the present invention is to provide a DMOS device whose carrier potential under the edge of the gate is reduced.

Further another object of the present invention is to provide a lateral DMOS device which can be manufactured by simple process.

In a lateral DMOS device, according to the present invention, a gate is formed above a substrate with a gate dielectric therebetween, a pair of source and drain are formed on the substrate at opposite sides of the gate, a body nearby the source has a portion under the gate, a drain diffusion region is provide between the drain and the body, and an insulator on the drain diffusion region is not overlapped by the gate over the drain diffusion region.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a conventional lateral DMOS device;

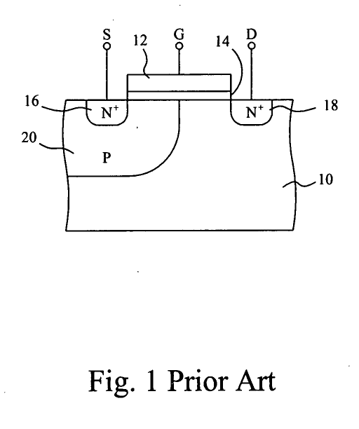

FIG. 2 shows another conventional lateral DMOS device;

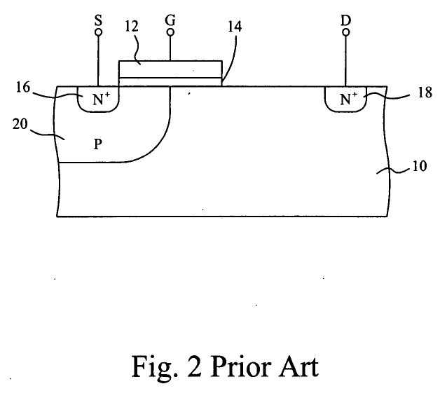

FIG. 3 shows a further conventional lateral DMOS device;

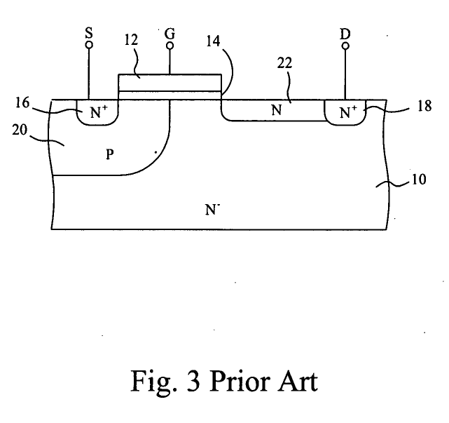

FIG. 4 shows a conventional RESURF DMOS device;

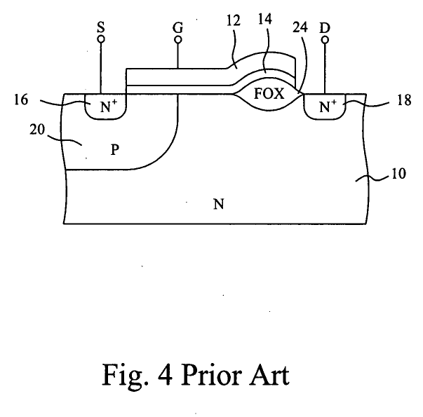

FIG. 5 shows a first embodiment according to the present invention;

FIG. 6 shows a second embodiment according to the present invention; and

FIG. 7 shows a third embodiment according to the present invention.

### DETAILED DESCRIPTION OF THE INVENTION

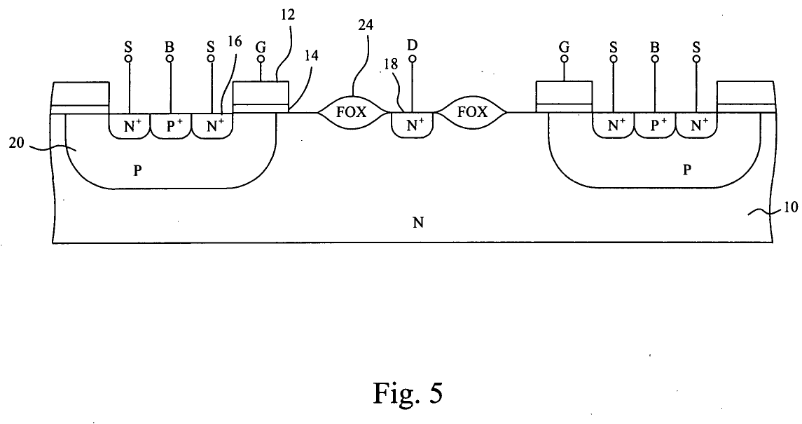

FIG. 5 shows a cross-sectional view of a pair of lateral DMOS transistors according to the present invention. Above an N substrate 10 is formed a polysilicon gate 12 with a gate oxide 14 therebetween, a source 16 and a drain 18 are formed on the substrate 10, a P-body 20 is also formed on the substrate 10 for the source 16 totally therewithin and has a portion under the gate 12, the substrate 10 provides a drain diffusion region between the P-body 20 and the drain 18, and a field oxide 24 is formed on the drain diffusion region. Particularly, the gate 12 does not overlap with the field oxide 24 over the drain diffusion region. The source 16 and the drain 18 have N conductivity type and dopant concentration higher than that in the substrate 10. The substrate 10 is a lightly doped one.

The field oxide 24 on the drain diffusion region is very helpful to reduce the lateral electric field under silicon surface. Further, the silicon surface under the field oxide 24 sinks and thereby lengthens the path across the depletion region. As a result, the distance between the drain 18 and the P-body 20 can be shorter for still sustaining high breakdown voltage. Over the drain diffusion region, the gate 12 does not overlap with the field oxide 24, and the device is therefore insensitive to oxide corner loss.

It is also advantageous that such structure requires very simple manufacture process and no additional steps, since the original field oxide process is sufficient.

In other embodiments, the gate oxide 14 can be replaced by other dielectrics, and the field oxide 24 can be replaced by other insulators, for example shallow trench isolation.

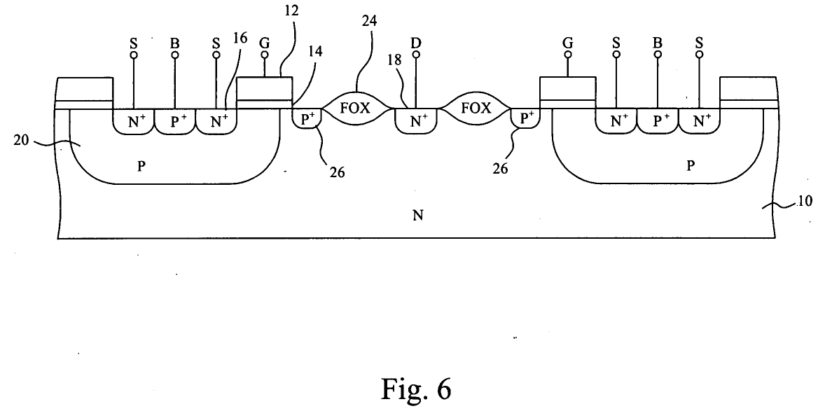

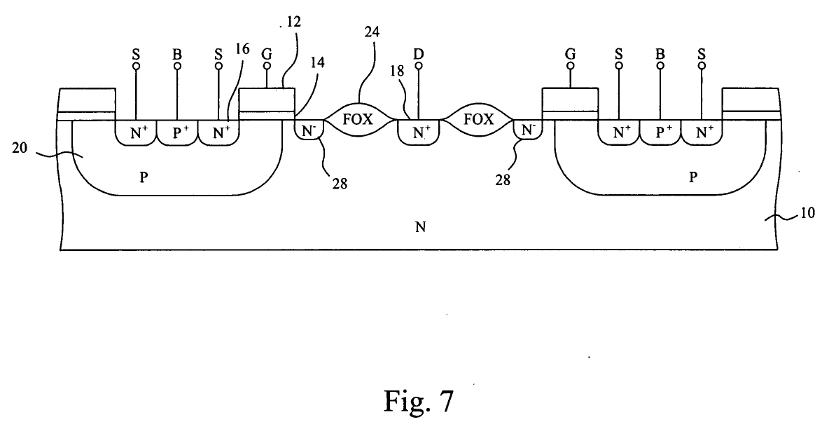

In FIG. 5, two lateral DMOS transistors are shown on the left side and the right side, and connected in series by the drain 18. For an example, this device may serve as a power stage of a power converter. FIG. 6 shows a further improvement, in which a P+ region 26 is additionally provided between the field oxide 24 and the gate 12 of each lateral DMOS transistor, whose dopant concentration is higher than that in the substrate 10 to further increase the breakdown voltages of the lateral DMOS transistors. Another improvement is shown in FIG. 7, which additionally provides a N- region 28 between the field oxide 24 and the gate 12 of each lateral DMOS transistor, having dopant concentration higher than that in the substrate 10 to thereby further reduce the on-resistance of the drain diffusion region.

The substrate 10 refers to any semiconductor material for manufacturing DMOS structure, for example an epitaxial layer, or a well in an epitaxial layer or other substrate.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A lateral DMOS device comprising:
a gate above a substrate;
a gate dielectric between said gate and said substrate;
a pair of source and drain on said substrate at opposite sides of the gate respectively;
a body nearby said source having a portion under said gate;
a drain diffusion region between said drain and said body; and
an insulator on said drain diffusion region;
wherein said gate does not overlap with said insulator over said drain diffusion region.

2. The device of claim 1, wherein said gate comprises a polysilicon.

3. The device of claim 1, wherein said source has a first conductivity type, and said body has a second conductivity type opposite to said first conductivity type.

4. The device of claim 3, further comprising a doped region of said second conductivity type on said drain diffusion region and between said gate and said insulator.

5. The device of claim 4, wherein said doped region has a dopant concentration higher than said drain diffusion region.

6. The device of claim 3, wherein said drain diffusion region has said first conductivity type.

7. The device of claim 6, further comprising a doped region of said first conductivity type on said drain diffusion region and between said gate and said insulator.

8. The device of claim 7, wherein said doped region has a dopant concentration higher than said drain diffusion region.

9. The device of claim 1, wherein said insulator comprises a field oxide.

10. The device of claim 1, wherein said insulator comprises a shallow trench isolation.
